(19) United States
(12) Patent Application Publication
(10) Pub. No.: US 2025/0151600 A1
(43) Pub. Date: May 8, 2025

(54) MASK ASSEMBLY AND METHOD OF MANUFACTURING THE SAME

(71) Applicant: Samsung Display Co., Ltd., Yongin-si (KR)

(72) Inventors: Jeongkuk Kim, Yongin-si (KR); Sungwon Cho, Yongin-si (KR); Junho Jo, Yongin-si (KR)

(73) Assignee: Samsung Display Co., Ltd., Yongin-si (KR)

(21) Appl. No.: 18/938,598

(22) Filed: Nov. 6, 2024

(30) Foreign Application Priority Data
Nov. 7, 2023 (KR) 10-2023-0153094

(51) Int. Cl. H10K 71/16; H10K 59/12

(52) U.S. Cl. CPC H10K 71/166; H10K 59/1201

(57) ABSTRACT

A mask assembly includes a mask frame including an opening area, and a mask sheet located on the mask frame and including a body portion, a rib portion, and a sheet portion. The body portion is formed along a circumference of a through-area at a center and define the through-area, the rib portion protrudes to the through-area and includes a plurality of first ribs extending in a first direction and a plurality of second ribs extending in a second direction intersecting the first direction to define a plurality of openings, and the sheet portion covers the through-area and includes a plurality of pattern holes overlapping the plurality of openings in a plan view.

### CROSS-REFERENCE TO RELATED APPLICATION(S)

This application claims priority to and benefits of Korean Patent Application No. 10-2023-0153094 under 35 U.S.C. § 119, filed on Nov. 7, 2023, in the Korean Intellectual Property Office (KIPO), the entire contents of which are incorporated herein by reference.

### BACKGROUND

### 1. Technical Field

Embodiments relate to a mask assembly with improved deposition quality and a method of manufacturing the mask assembly.

### 2. Description of the Related Art

Recently, electronic devices have come into widespread use. Electronic devices are variously used as mobile electronic devices and fixed electronic devices. Such electronic devices include display apparatuses that may provide visual information such as images or videos to users to support various functions.

A display apparatus visually displays data and is formed by depositing various layers such as an organic layer, an inorganic layer, and a metal layer. A deposition material may be deposited to form multiple layers of the display apparatus. For example, a deposition material may be sprayed from a deposition source and deposited on a display substrate through a mask assembly.

When the mask assembly is more closely attached to the display substrate, a shadow effect may be reduced, and deposition quality may be improved.

The background described above is technical information that the inventor possessed for the derivation of the disclosure or acquired in the derivation process of the disclosure, and it may not be said that it is known technology disclosed to the general public before the filing of the disclosure.

### SUMMARY

Embodiments include a mask assembly with improved deposition quality and a method of manufacturing the mask assembly.

However, problems to be solved by the disclosure are not limited thereto.

Additional aspects will be set forth in part in the description which follows and, in part, will be apparent from the description, or may be learned by practice of the embodiments.

According to an embodiment, a mask assembly may include a mask frame including an opening area, and a mask sheet located on the mask frame and including a body portion, a rib portion, and a sheet portion. The body portion may be formed along a circumference of a through-area at a center and define the through-area, the rib portion may protrude to the through-area and include a plurality of first ribs extending in a first direction and a plurality of second ribs extending in a second direction intersecting the first direction to define a plurality of openings, and the sheet portion may cover the through-area and includes a plurality of pattern holes overlapping the plurality of openings in a plan view.

The body portion may include a silicon material, and the rib portion may include a metal material.

The sheet portion may include a metal material or an inorganic material.

The rib portion may protrude so that a top surface of the rib portion is at a position higher than a top surface of the body portion.

The rib portion may protrude so that the top surface of the rib portion is higher than the top surface of the body portion by about 0.1 μm to about 5 μm.

A portion of the sheet portion overlapping the rib portion in a plan view may protrude to be higher than a portion of the sheet portion overlapping the plurality of openings in a plan view.

The portion of the sheet portion overlapping the rib portion in a plan view may protrude to be higher than the portion of the sheet portion overlapping the plurality of openings by about 0.1 μm to about 5 μm.

A thickness of the rib portion may be greater than a thickness of the sheet portion and less than a thickness of the body portion.

A thickness of the rib portion may be about 1/20 to about 1/10 of a thickness of the body portion.

A bottom surface of the rib portion may be located higher than a bottom surface of the body portion.

The body portion may include a receiving groove formed along an inner circumference of the body portion in a plan view, and the rib portion may be supported by and seated in the receiving groove.

According to an embodiment, a method of manufacturing a mask assembly may include forming a first groove extending in a first direction and a second groove extending in a second direction intersecting the first direction, by etching a top surface of a base layer including a silicon material, forming a rib portion by forming a metal layer in the first groove and the second groove, forming a sheet portion to cover the top surface of the base layer and the rib portion, and removing a portion of the base layer overlapping the sheet portion in a plan view to form a through-area.

The forming of the rib portion may include forming the metal layer so that a top surface of the rib portion is higher than the top surface of the base layer.

The top surface of the rib portion may protrude to be higher than the top surface of the base layer by about 0.1 μm to about 5 μm.

A bottom surface of the rib portion may be located higher than a bottom surface of the base layer.

The forming of the sheet portion may include forming a plurality of pattern holes by forming a second metal layer by using electroforming.

The forming of the sheet portion may include forming a plurality of pattern holes by forming and etching an inorganic film including an inorganic material.

The forming of the sheet portion may include allowing a portion of the sheet portion overlapping the rib portion in a plan view to protrude to be at a position higher than a portion of the sheet portion not overlapping the rib portion in a plan view.

A thickness of the rib portion may be greater than a thickness of the sheet portion and less than a thickness of the base layer.

The removing of the portion of the base layer may include removing the portion of the base layer so that the base layer is arranged in a ring shape along a circumference of the sheet portion.

Other aspects, features, and advantages of the disclosure will become more apparent from the detailed description, the claims, and the drawings.

### BRIEF DESCRIPTION OF THE DRAWINGS

The above and other aspects, features, and advantages of certain embodiments will be more apparent from the following description taken in conjunction with the accompanying drawings, in which:

FIG. 1 is a schematic cross-sectional view illustrating an apparatus for manufacturing a display apparatus, according to an embodiment;

FIG. 2 is a plan view schematically illustrating a mask assembly, according to an embodiment;

FIG. 3 is an enlarged view illustrating portion III of FIG. 2;

FIG. 4 is a schematic cross-sectional view illustrating the mask assembly, taken along a line IV-IV′ of FIG. 3, according to an embodiment;

FIGS. 5 to 14 are schematic cross-sectional views schematically illustrating a method of manufacturing a mask assembly, according to an embodiment;

FIGS. 15 and 16 are schematic cross-sectional views schematically illustrating a method of manufacturing a mask assembly, according to an embodiment;

FIG. 17 is a perspective view schematically illustrating a display apparatus manufactured by using an apparatus for manufacturing a display apparatus, according to an embodiment;

FIG. 18 is a schematic diagram of an equivalent circuit of one pixel circuit included in a display apparatus manufactured by using an apparatus for manufacturing a display apparatus, according to an embodiment; and

FIG. 19 is a schematic cross-sectional view schematically illustrating a display apparatus manufactured by using an apparatus for manufacturing a display apparatus, according to an embodiment.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description. As used herein, the term “and/or” includes any and all combinations of one or more of the associated listed items.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

As the disclosure allows for various changes and numerous embodiments, certain embodiments will be illustrated in the drawings and described in the detailed description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described in detail with reference to the accompanying drawings, wherein the same or corresponding elements are denoted by the same reference numerals throughout and a repeated description thereof is omitted.

Although the terms “first,” “second,” etc. may be used to describe various elements, these elements should not be limited by these terms. These terms are only used to distinguish one element from another.

As used herein, the singular forms “a,” “an,” and “the” are intended to include the plural forms as well, unless the context clearly indicates otherwise.

It will be understood that the terms “including,” and “having,” are intended to indicate the existence of the features or elements described in the specification, and are not intended to preclude the possibility that one or more other features or elements may exist or may be added.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Sizes of components in the drawings may be exaggerated or reduced for convenience of explanation. For example, because sizes and thicknesses of components in the drawings are arbitrarily illustrated for convenience of explanation, the disclosure is not limited thereto.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

In the following embodiments, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When a certain embodiment may be implemented differently, a specific process order may be different from the described order. For example, two consecutively described processes may be performed substantially at the same time or may be performed in an order opposite to the described order.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

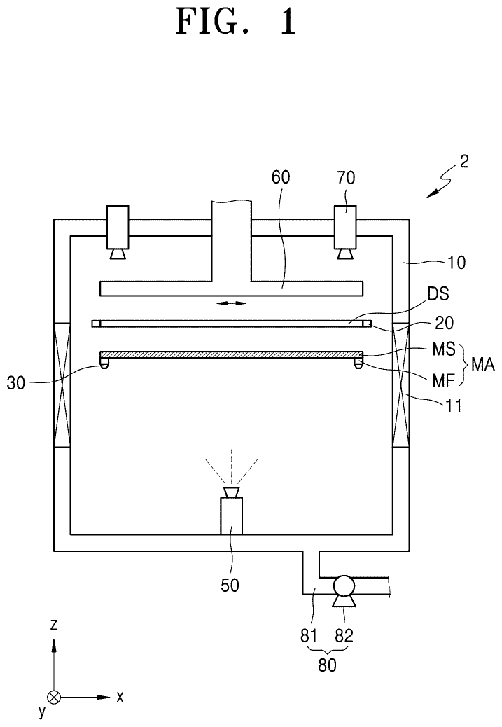

FIG. 1 is a schematic cross-sectional view illustrating an apparatus for manufacturing a display apparatus, according to an embodiment.

An apparatus 2 for manufacturing a display apparatus may include a chamber 10, a first support 20, a second support 30, a mask assembly MA, a deposition source 50, a magnetic force unit 60, a vision unit 70, and a pressure control unit 80.

The chamber 10 may have an inner space, and a display substrate DS and the mask assembly MA may be accommodated in the chamber 10. A portion of the chamber 10 may be open, and a gate valve 11 may be provided at the open portion of the chamber 10. The open portion of the chamber 10 may be opened or closed according to an operation of the gate valve 11.

The display substrate DS may be a display substrate DS under manufacturing of a display apparatus, in which at least one of an organic layer, an inorganic layer, and a metal layer is deposited on a substrate 100 described below. In another embodiment, the display substrate DS may be a substrate 100 on which any of an organic layer, an inorganic layer, and a metal layer is not yet deposited.

The first support 20 may support the display substrate DS. In an embodiment, the first support 20 may be of a plate type fixed in the chamber 10. In another embodiment, the first support 20 may be of a shuttle type on which the display substrate DS may be seated and that is linearly movable in the chamber 10. In another embodiment, the first support 20 may include an electrostatic chuck or an adhesive chuck that is fixed to the chamber 10 or is located in the chamber 10 to be movable in the chamber 10.

The second support 30 may support the mask assembly MA. The second support 30 may be located in the chamber 10. The second support 30 may finely adjust a position of the mask assembly MA. The second support 30 may include a separate driver or alignment unit to move the mask assembly MA in directions.

In another embodiment, the second support 30 may be of a shuttle type. The mask assembly MA may be seated on the second support 30, and the second support 30 may move the mask assembly MA. For example, the second support 30 may move to the outside of the chamber 10, may allow the mask assembly MA to be seated thereon, and may enter the chamber 10 from the outside of the chamber 10.

In an embodiment, the first support 20 and the second support 30 may be integrally formed with each other. The first support 20 and the second support 30 may each include a movable shuttle. The first support 20 and the second support 30 may include a structure for fixing the mask assembly MA and the display substrate DS in a state where the display substrate DS is seated on the mask assembly MA, and may linearly move the display substrate DS and the mask assembly MA at the same time.

However, for convenience of explanation, an embodiment that the first support 20 and the second support 30 are formed to be distinguished from each other and located at different positions, and the first support 20 and the second support 30 are located in in the chamber 10 will be described.

The deposition source 50 may be located to face the mask assembly MA. A deposition material may be accommodated in the deposition source 50, and the deposition material may be vaporized or sublimated by applying heat to the deposition material. The deposition source 50 may be located in the chamber 10 to be fixed in the chamber 10 or to be linearly movable in a direction.

The mask assembly MA may be located in the chamber 10. The mask assembly MA may include a mask frame MF and a mask sheet MS, which will be described below in detail. The deposition material may pass through the mask assembly MA and may be deposited on the display substrate DS.

The magnetic force unit 60 may be located in the chamber 10 to face the display substrate DS and/or the mask assembly MA. The magnetic force unit 60 may apply a force to the mask assembly MA toward the display substrate DS by applying a magnetic force to the mask assembly MA. For example, the magnetic force unit 60 may prevent sagging of the mask sheet MS and may keep the mask sheet MS to be adjacent to the display substrate DS. The magnetic force unit 60 may maintain a uniform interval between the mask sheet MS and the display substrate DS.

The vision unit 70 may be located in the chamber 10 and may obtain an image of positions of the display substrate DS and the mask assembly MA. The vision unit 70 may include a camera for photographing the display substrate DS and the mask assembly MA. The positions of the display substrate DS and the mask assembly MA may be identified based on the image obtained by the vision unit 70, and deformation of the mask assembly MA may be identified based on the image obtained by the vision unit 70. Also, based on the image, the position of the display substrate DS on the first support 20 may be finely adjusted, or the position of the mask assembly MA on the second support 30 may be finely adjusted. However, the following will be described in detail assuming that the positions of the display substrate DS and the mask assembly MA are aligned with each other by finely adjusting the position of the mask assembly MA on the second support 30.

The pressure control unit 80 may be connected to the chamber 10 and may adjust a pressure in the chamber 10. For example, the pressure control unit 80 may adjust a pressure in the chamber 10 to be the same as or similar to atmospheric pressure. The pressure control unit 80 may adjust a pressure in the chamber 10 to be the same as or similar to that in a vacuum state.

The pressure control unit 80 may include a connection pipe 81 connected to the chamber 10 and a pump 82 provided on the connection pipe 81. According to an operation of the pump 82, external air may be introduced through the connection pipe 81, or gas in the chamber 10 may be guided to the outside through the connection pipe 81.

In a method of manufacturing a display apparatus (not shown) by using the apparatus 2 for manufacturing a display apparatus, first, the display substrate DS may be prepared.

The pressure control unit 80 may maintain a pressure in the chamber 10 to be the same as or similar to atmospheric pressure, and the gate valve 11 may operate to open the open portion of the chamber 10.

The display substrate DS may be moved from the outside into the chamber 10. The display substrate DS may be loaded into the chamber 10 in various ways. For example, the display substrate DS may be loaded from the outside of the chamber 10 into the chamber 10 through a robot arm or the like located outside the chamber 10. In another embodiment, in case that the first support 20 is of a shuttle type, the first support 20 may be carried from the chamber 10 to the outside of the chamber 10, and the display substrate DS may be seated on the first support 20 through the robot arm or the like located outside the chamber 10, and the first support 20 may be moved from the outside of the chamber 10 into the chamber 10.

The mask assembly MA may be located in the chamber 10 as described above. In another embodiment, the mask assembly MA may be loaded from the outside of the chamber 10 into the chamber 10, in a manner identical or similar to that of the display substrate DS.

In case that the display substrate DS is loaded into the chamber 10, the display substrate DS may be seated on the first support 20. The vision unit 70 may obtain an image of positions of the display substrate DS and the mask assembly MA. The positions of the display substrate DS and the mask assembly MA may be identified based on the image obtained by the vision unit 70. The apparatus 2 for manufacturing a display apparatus may include a separate controller (not shown) and may identify the positions of the display substrate DS and the mask assembly MA.

In case that the positions of the display substrate DS and the mask assembly MA are completely identified, the second support 30 may finely adjust the position of the mask assembly MA.

The deposition source 50 may operate to supply the deposition material to the mask assembly MA, and the deposition material passing through multiple pattern holes of the mask sheet MS may be deposited on the display substrate DS. The deposition source 50 may move parallel to the display substrate DS and the mask assembly MA, or the display substrate DS and the mask assembly MA may move parallel to the deposition source 50. For example, the deposition source 50 may move relative to the display substrate DS and the mask assembly MA. The pump 82 may maintain a pressure in the chamber 10 to be the same as or similar to vacuum, by sucking gas in the chamber 10 and discharging the gas to the outside.

As described above, the deposition material supplied by the deposition source 50 may pass through the mask assembly MA and may be deposited on the display substrate DS, to form at least one of multiple layers, for example, an organic layer, an inorganic layer, and a metal layer, stacked in a display apparatus described below.

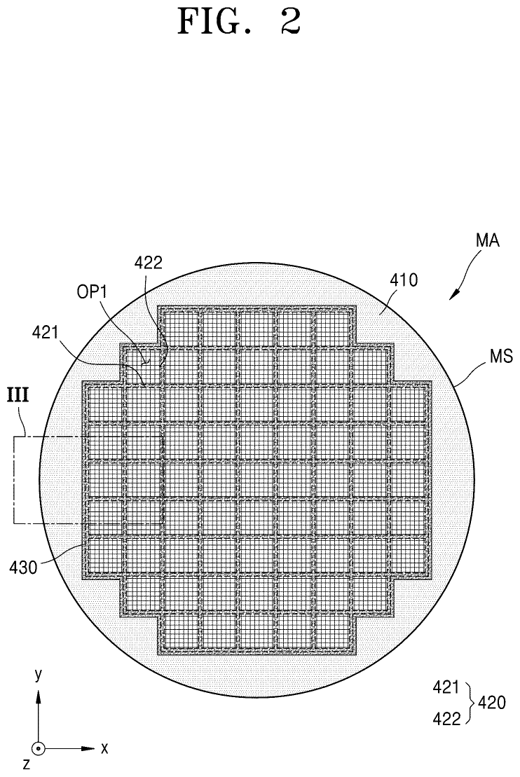

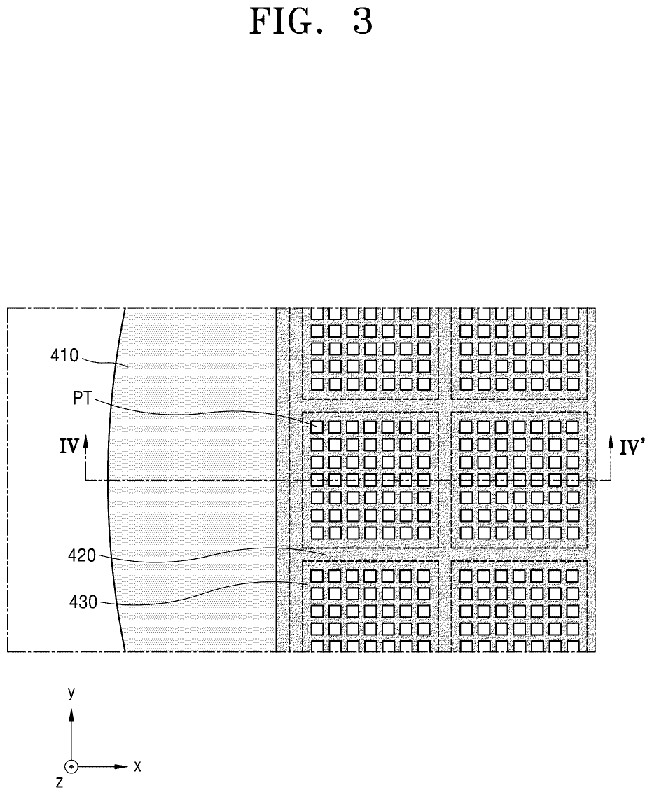

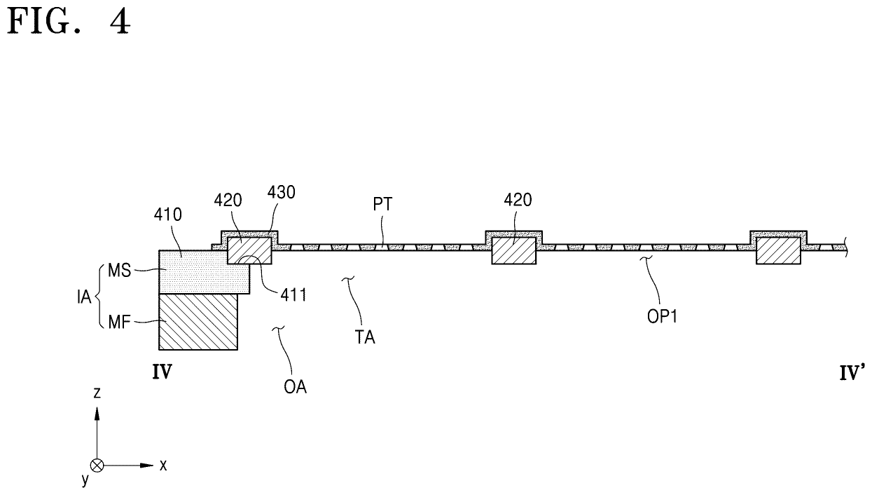

FIG. 2 is a plan view schematically illustrating a mask assembly, according to an embodiment. FIG. 3 is an enlarged view illustrating portion III of FIG. 2. FIG. 4 is a schematic cross-sectional view schematically illustrating the mask assembly, taken along line IV-IV′ of FIG. 3, according to an embodiment.

Referring to FIGS. 2 to 4, the mask assembly MA may include the mask frame MF and the mask sheet MS.

The mask frame MF may be a frame that supports the mask sheet MS and includes an opening area OA at the center. In an embodiment, the mask frame MF may be a circular frame, and the opening area OA may also be defined as a circular area. A shape of the mask frame MF is not limited thereto and may be any of various polygonal shapes. For convenience of explanation, the following will be described assuming that the mask frame MF is a circular frame.

The mask sheet MS may be provided on the mask frame MF. The opening area OA at the center of the mask frame MF may be covered by the mask sheet MS. In an embodiment, the mask sheet MS may be fixed to the mask frame MF by using welding. In an embodiment, the mask sheet MS may have a circular shape corresponding to a shape of the opening area OA of the mask frame MF.

The mask sheet MS may include a body portion 410, a rib portion 420, and a sheet portion 430.

The body portion 410 may include a silicon material. For example, the body portion 410 may include at least one of silicon oxide (SiOₓ), silicon nitride (SiNₓ), and silicon oxynitride (SiOₓN_{y}).

The body portion 410 may be formed to correspond to a shape of the mask frame MF. For example, the body portion 410 may be formed to have a circular shape corresponding to a circumferential shape of the mask frame MF. However, the disclosure is not limited thereto, and the body portion 410 may be formed in any of various polygonal shapes. For convenience of explanation, the following will be described assuming that the body portion 410 has a circular shape to correspond to the shape of the mask frame MF.

The body portion 410 may include a through-area TA at the center. The through-area TA may be an open area located at the center of the body portion 410 and completely passing through the body portion 410. The through-area TA may be an area through which a deposition material passes. The body portion 410 may be formed in a closed loop shape, for example, a ring shape, along a circumference of the through-area TA to surround the through-area TA in a plan view. In an embodiment, a thickness of the body portion 410 may be in a range of about 600 μm to about 800 μm. For example, a thickness of the body portion 410 may be about 720 μm.

The rib portion 420 may cover the through-area TA of the body portion 410. The rib portion 420 may include a metal material. For example, the rib portion 420 may include at least one of aluminum (Al), copper (Cu), titanium (Ti), and molybdenum (Mo).

In an embodiment, the rib portion 420 may be arranged in a lattice shape. For example, the rib portion 420 may include a first rib 421 extending in a first direction (e.g., an x direction of FIG. 2) and a second rib 422 extending in a second direction (e.g., a y direction of FIG. 2) intersecting the first direction in a plan view. In an embodiment, multiple first ribs 421 and multiple second ribs 422 may be provided. The first ribs 421 may be spaced apart from each other in the second direction and may extend parallel to each other. The second ribs 422 may be spaced apart from each other in the first direction and may extend parallel to each other. Accordingly, the first ribs 421 and the second ribs 422 may be arranged in a lattice shape to define multiple first openings OP1. In other words, the first rib 421 and the second rib 422 may surround the first opening OP1 and define the first opening OP1.

In an embodiment, each of the first openings OP1 may have a quadrangular shape in a plan view. A shape of each of the first openings OP1 may correspond to a shape of a display panel. For example, each of the first openings OP1 may correspond to a shape of a cell.

In an embodiment, the body portion 410 may include a receiving groove 411 in which the rib portion 420, for example, the first rib 421 and the second rib 422, is accommodated. For example, the first rib 421 and the second rib 422 adjacent to the body portion 410 located to surround the through-area TA from among the first ribs 421 and the second ribs 422 covering the through-area TA may be supported and seated in the receiving groove 411. In other words, the receiving groove 411 may be formed along an inner circumference of the body portion 410 having a closed loop shape.

A thickness of the rib portion 420 may be in a range of about 10 μm to about 70 μm. A thickness of the rib portion 420 may be less than a thickness of the body portion 410. For example, a thickness of the rib portion 420 may be in a range of about 1/20 to about 1/10 of a thickness of the body portion 410. A top surface of the rib portion 420 (e.g., a surface in a +z direction of FIG. 4) may protrude to be at a position higher than a top surface of the body portion 410 (e.g., a surface in the +z direction of FIG. 4). In other words, a plane including a top surface of the rib portion 420 may be spaced apart from and at a higher position in the +z direction than a plane including a top surface of the body portion 410. For example, a top surface of the rib portion 420 may protrude to be at a position higher than a top surface of the body portion 410 by about 0.1 μm to about 5 μm.

Because a thickness of the rib portion 420 is less than a thickness of the body portion 410, a bottom surface of the rib portion 420 (e.g., a surface in a-z direction of FIG. 4) may be located higher than a bottom surface of the body portion 410 (e.g., a surface in the −z direction of FIG. 4). In other words, a plane including a bottom surface of the rib portion 420 may be spaced apart from and at a higher position in the +Z direction than a plane including a bottom surface of the body portion 410.

The sheet portion 430 may be located to cover the through-area TA. The sheet portion 430 may be located to cover the rib portion 420 located across the through-area TA. Because the sheet portion 430 covers the rib portion 420, a portion of the sheet portion 430 overlapping the rib portion 420 may protrude from a portion of the sheet portion 430 not overlapping the rib portion 420 in a plan view. For example, a portion of the sheet portion 430 overlapping the rib portion 420 in a plan view may protrude by about 0.1 μm to about 5 μm.

In an embodiment, the sheet portion 430 may include a metal material. For example, the sheet portion 430 may include at least one of aluminum (Al), copper (Cu), titanium (Ti), and molybdenum (Mo). In another embodiment, the sheet portion 430 may include an inorganic material. For example, the sheet portion 430 may include at least one of silicon oxide (SiOₓ), silicon nitride (SiNₓ), and silicon oxynitride (SiOₓN_{y}).

In an embodiment, the sheet portion 430 may include multiple pattern holes PT overlapping the first openings OP1 in a plan view. In an embodiment, shapes of the pattern holes PT may correspond to a shape of a deposition pattern to be deposited on the display substrate DS. For example, the pattern holes PT may have shapes corresponding to an emission layer pattern of a pixel to be deposited on the display substrate DS. Accordingly, a deposition material may pass through the pattern holes PT to form an emission layer on the display substrate DS.

In an embodiment, a thickness of the sheet portion 430 may be in a range of about 1 μm to about 5 μm. A thickness of the sheet portion 430 may be less than a thickness of the rib portion 420.

In the mask sheet MS according to an embodiment, the body portion 410 including a silicon material may form a circumference of the mask sheet MS, and the rib portion 420 including a metal material may be arranged in a lattice shape. The sheet portion 430 having a thickness less than a thickness of the rib portion 420 may be located to cover the rib portion 420. To closely attach the mask sheet MS to the display substrate DS, a magnetic force of the magnetic force unit 60 may be applied. Because the body portion 410 does not include a metal material and the sheet portion 430 is a very thin film that is not thick enough to be affected by a magnetic force, a separate element for forcing the mask sheet MS toward the display substrate DS may be required. However, because the rib portion 420 has a sufficient thickness and is arranged in a lattice shape across the through-area TA of the mask sheet MS, the rib portion 420 may function as an open mask that is open corresponding to a cell area, and a magnetic force of the magnetic force unit 60 of the apparatus for manufacturing a display apparatus may be effectively applied. Accordingly, a separate element such as a mask support for closely attaching the mask sheet MS toward the display substrate DS may not be required. Also, as the mask sheet MS is closely attached to the display substrate DS, a shadow effect may be prevented and sagging of the mask sheet MS may also be prevented.

Because a top surface of the rib portion 420 protrudes to be at a position higher than a top surface of the body portion 410, a portion of the sheet portion 430 overlapping the rib portion 420 may protrude, and may first contact the display substrate DS in case that the sheet portion 430 is closely attached to the display substrate DS. Accordingly, damage to a deposition area of the display substrate DS due to contact between the deposition area of the display substrate DS and the sheet portion 430 may be prevented.

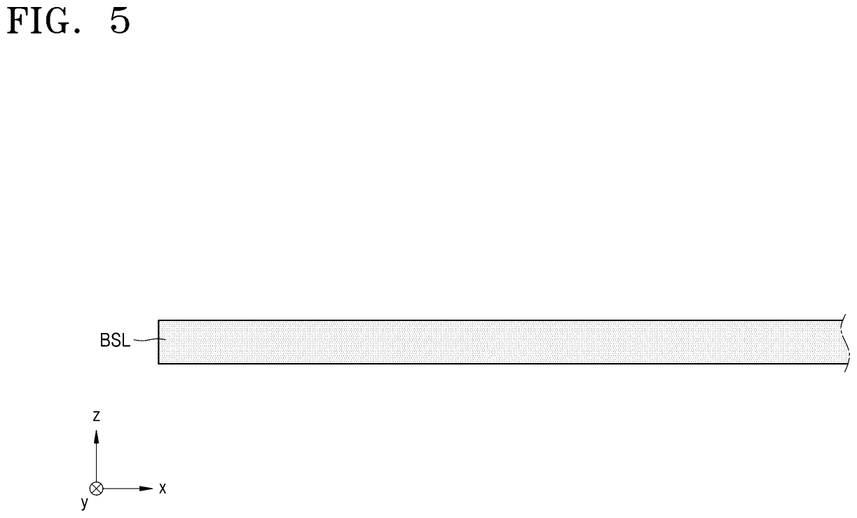

FIGS. 5 to 14 are schematic cross-sectional views schematically illustrating a method of manufacturing a mask assembly, according to an embodiment.

A method of manufacturing a mask assembly according to the embodiment may be used to manufacture the mask assembly described above, but the disclosure is not limited thereto.

Referring to FIG. 5, a base layer BSL that is formed as the body portion 410 later may be located. As described above, the base layer BSL may include a silicon material, for example, at least one of silicon oxide (SiOₓ), silicon nitride (SiNₓ), and silicon oxynitride (SiOₓN_{y}).

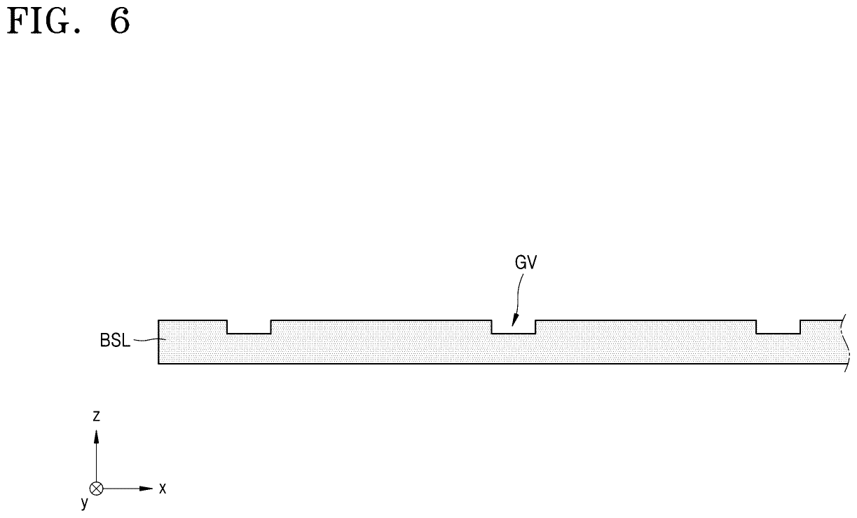

Referring to FIG. 6, a top surface of the base layer BSL (e.g., a surface in the +z direction of FIG. 6) may be etched. For example, the top surface of the base layer BSL may be etched to form a groove GV. The groove GV may include a first groove extending in the first direction and a second groove extending in the second direction intersecting the first direction. In an embodiment, multiple first grooves and multiple second grooves may be provided. The first grooves may be spaced apart from each other in the second direction and may extend parallel to each other. The second grooves may be spaced apart from each other in the first direction and may extend parallel to each other. Accordingly, the first grooves and the second grooves may be arranged in a lattice shape to define multiple cell areas.

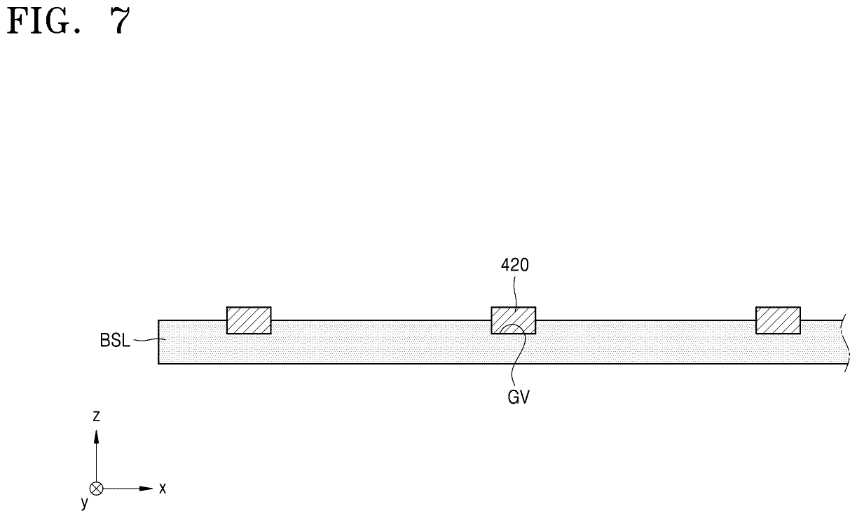

Referring to FIG. 7, a metal layer may be formed in the groove GV, specifically, the first groove and the second groove. For example, the metal layer may include at least one of aluminum (Al), copper (Cu), titanium (Ti), and molybdenum (Mo). Accordingly, the metal layer may be formed in a lattice shape along the first groove and the second groove. Accordingly, the rib portion 420 as described above may be formed. The metal layer may be formed so that a top surface of the rib portion (e.g., a surface in the +z direction of FIG. 7) is at a position higher than a top surface of the base layer BSL (e.g., a surface in the +z direction of FIG. 7). For example, the metal layer may be formed higher than a plane including the top surface of the base layer BSL. In an embodiment, the metal layer may be formed higher than the top surface of the base layer BSL by about 0.1 μm to about 5 μm.

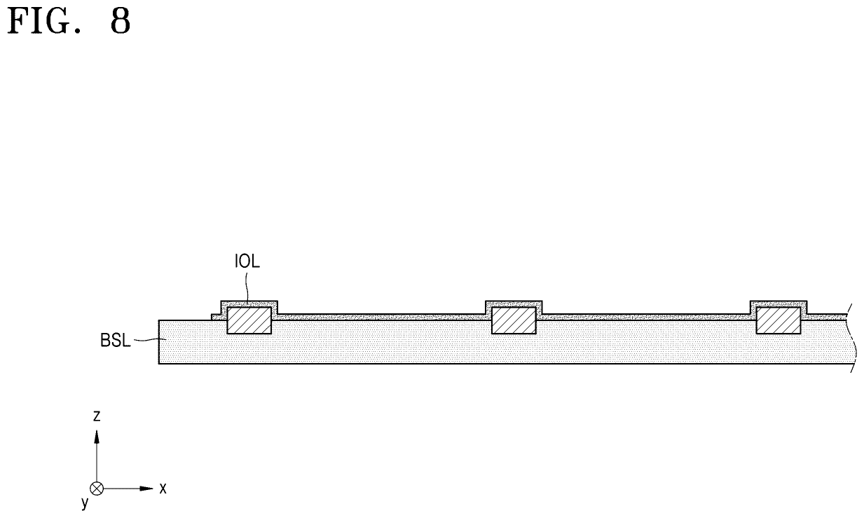

Referring to FIG. 8, an inorganic film IOL may be formed to cover the top surface of the base layer BSL and the rib portion 420. For example, the inorganic film IOL may include an inorganic material, for example, at least one of silicon oxide (SiOₓ), silicon nitride (SiNₓ), and silicon oxynitride (SiOₓN_{y}). The inorganic film IOL may be located to cover the rib portion 420 and the cell area defined in the base layer BSL. In other words, the inorganic film IOL may not be located at a circumference of the base layer BSL.

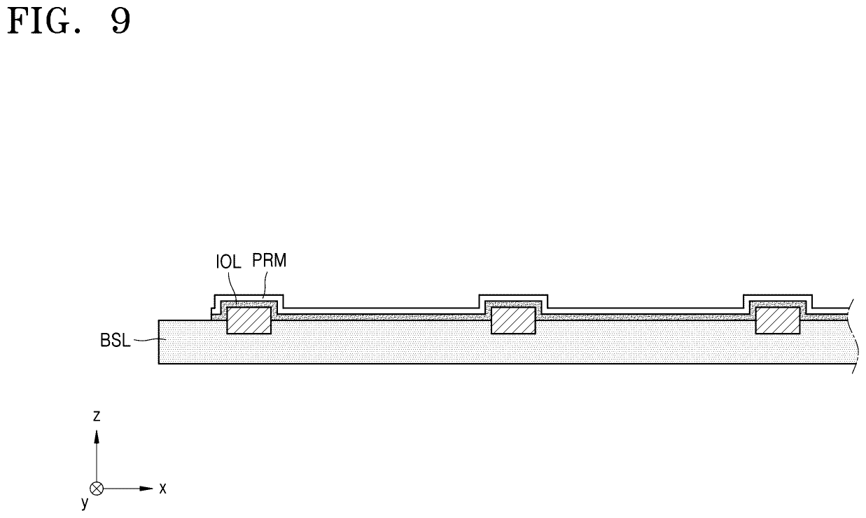

Referring to FIG. 9, a photoresist material PRM may be formed on the inorganic film IOL. The photoresist material PRM may be a photosensitive material.

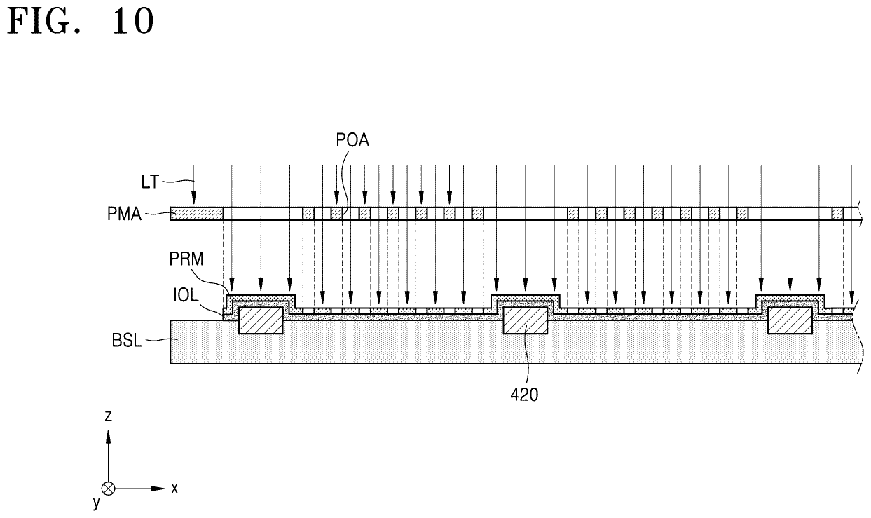

Referring to FIG. 10, a photomask PMA including an opening POA may be located on the photoresist material PRM. The photoresist material PRM may be exposed through the opening POA of the photomask PMA. Light LT may pass through the opening POA and may come into contact with the photoresist material PRM. For example, the light LT may be ultraviolet rays. In this process, the solubility of the photoresist material PRM overlapping the opening POA in a plan view may decrease. The solubility of the photoresist material PRM not overlapping the opening POA in a plan view may increase.

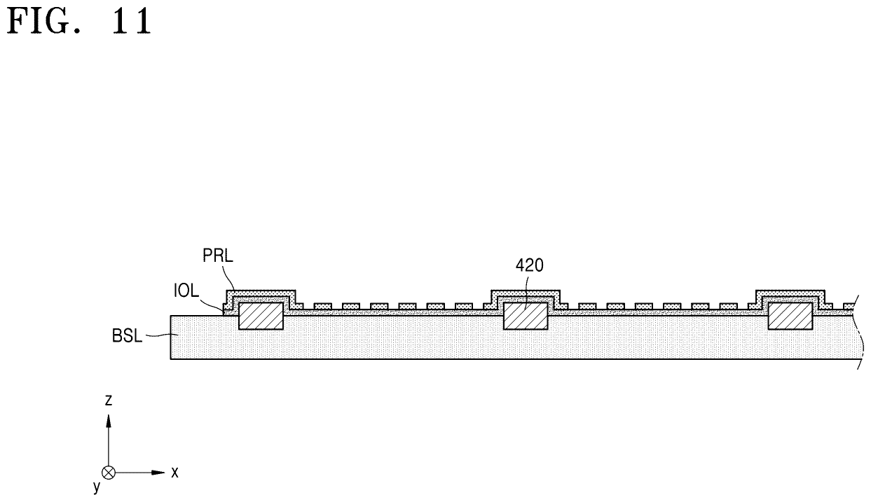

Referring to FIG. 11, the photoresist material PRM may be developed into a photoresist layer PRL. For example, a part of the photoresist material PRM may be removed by using an alkaline developer. The photoresist material PRM that is not in contact with ultraviolet rays may be removed. The photoresist layer PRL may be located so as not to overlap the rib portion 420 in a plan view, and may be located on the cell area defined in the base layer BSL.

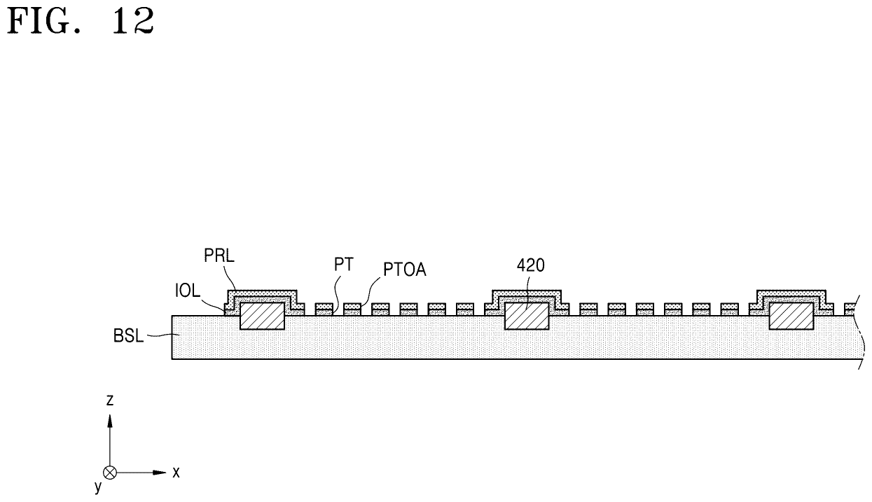

Referring to FIG. 12, a portion of the inorganic film IOL overlapping a photo-opening PTOA in a plan view may be etched. A portion of the inorganic film IOL overlapping the photoresist layer PRL in a plan view may remain, and a portion overlapping the photo-opening PTOA in a plan view may be removed. In an embodiment, the inorganic film IOL may be etched by using dry etching through etching gas. As the inorganic film IOL is etched, the pattern hole PT may be formed to form the sheet portion 430 as described above.

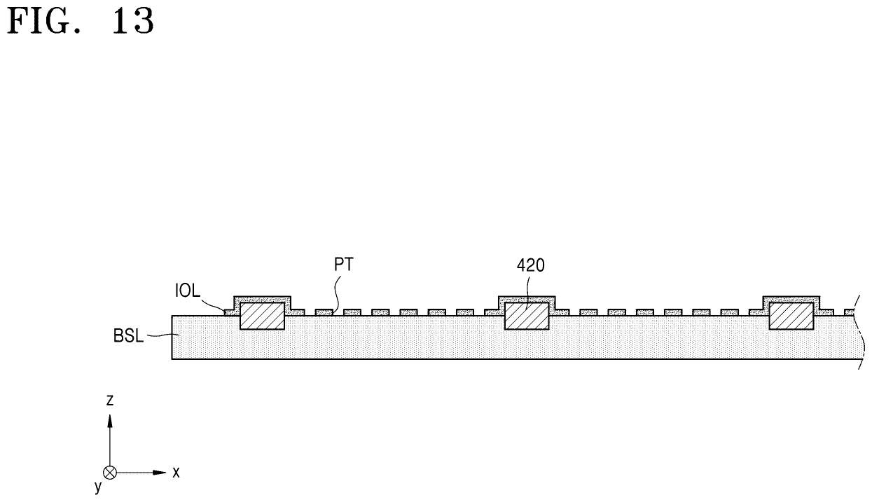

Referring to FIG. 13, the photoresist layer PRL may be removed. As the photoresist layer PRL is removed, a top surface of the inorganic film IOL may be exposed.

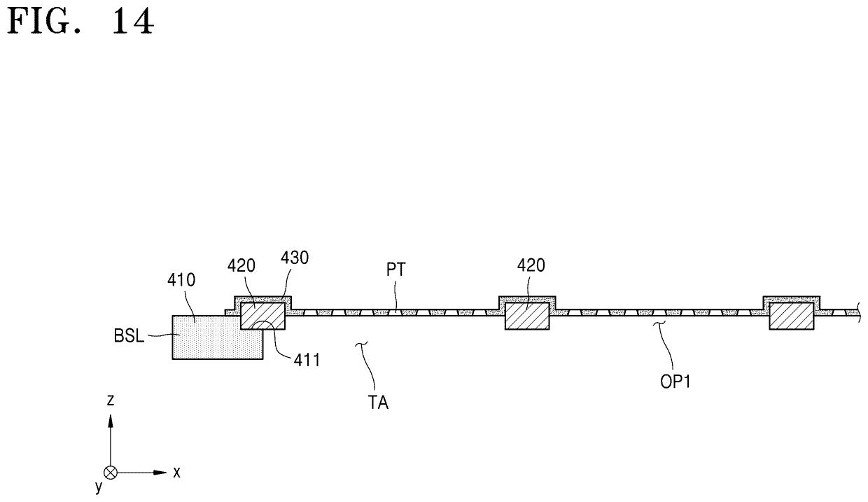

Referring to FIG. 14, a part of the base layer BSL may be removed. In an embodiment, a portion of the base layer BSL overlapping the sheet portion 430 in a plan view may be removed. In other words, as a central portion of the base layer BSL is removed, the body portion 410 including the through-area TA may be formed. The body portion 410 may be formed in a closed loop shape, for example, a ring shape, along a circumference of the through-area TA to surround the through-area TA in a plan view. The through-area TA may be formed by using a photolithography process. The photolithography process has been described with reference to FIGS. 9 to 13, and thus, a detailed description thereof will be omitted.

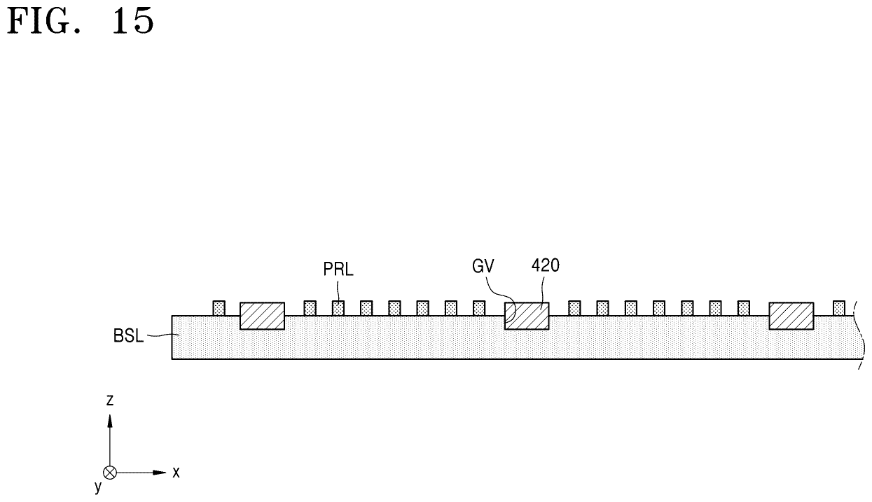

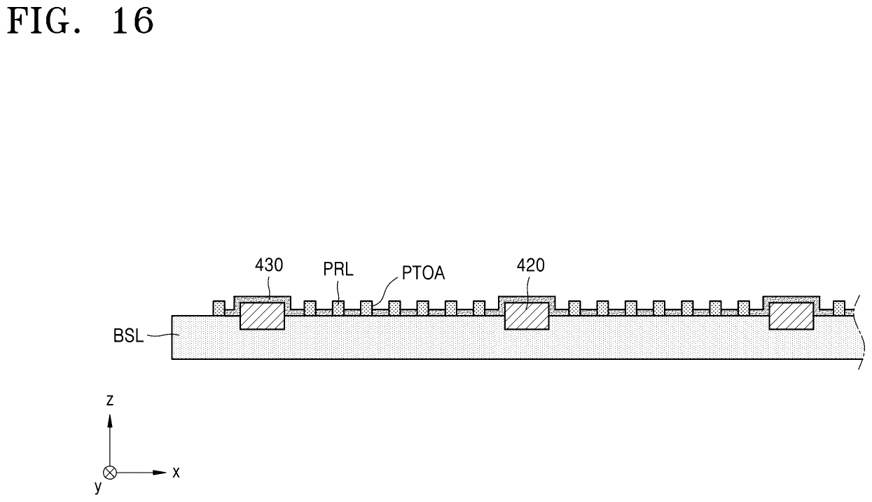

FIGS. 15 and 16 are schematic cross-sectional views schematically illustrating a method of manufacturing a mask assembly, according to an embodiment. A method of manufacturing a mask assembly according to the embodiment is similar to the manufacturing method described above, and thus, the following will focus on a difference.

Referring to FIG. 15, the rib portion 420 may be formed in the groove GV of the base layer BSL as described above. The photoresist layer PRL may be formed on the base layer BSL. The photoresist layer PRL may be located so as not to overlap the rib portion 420 in a plan view, and may be located on the cell area defined in the base layer BSL.

Referring to FIG. 16, the sheet portion 430 may be formed by using electroforming. The sheet portion 430 may be formed to fill the photo-opening PTOA of the photoresist layer PRL and may cover the base layer BSL and the rib portion 420. In an embodiment, a metal layer including a metal material may be formed by using electroforming to form the sheet portion 430.

As described with reference to FIGS. 13 and 14, the photoresist layer PRL may be removed. Also, a part of the base layer BSL, for example, a portion of the base layer BSL overlapping the sheet portion 430 in a plan view, may be removed. In other words, as a central portion of the base layer BSL is removed, the body portion 410 including the through-area TA may be formed.

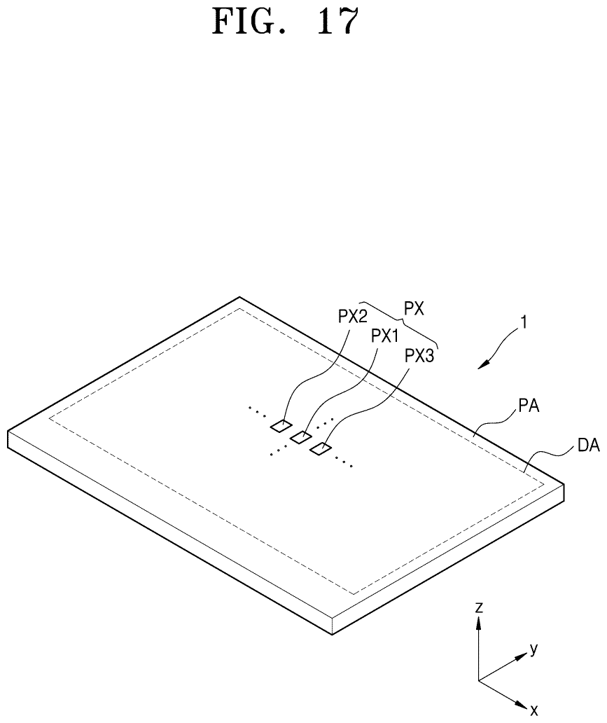

FIG. 17 is a perspective view schematically illustrating a display apparatus manufactured by using an apparatus for manufacturing a display apparatus, according to an embodiment.

Referring to FIG. 17, a display apparatus 1 may include a display area DA where an image is formed and a peripheral area PA where an image is not formed. The display apparatus 1 may provide an image through an array of pixels that are two-dimensionally arranged in an x-y plane of the display area DA. Each pixel may include sub-pixels. Each sub-pixel may emit light of a color. For example, each sub-pixel may be one of a green sub-pixel, a red sub-pixel, and a blue sub-pixel.

In an embodiment, multiple sub-pixels may include a first sub-pixel PX1, a second sub-pixel PX2, and a third sub-pixel PX3. For convenience of explanation, the following will be described assuming that the first sub-pixel PX1 is a green sub-pixel, the second sub-pixel PX2 is a red sub-pixel, and the third sub-pixel PX3 is a blue sub-pixel.

The first sub-pixel PX1, the second sub-pixel PX2, and the third sub-pixel PX3 may be areas that may respectively emit green light, red light, and blue light, and the display apparatus 1 may provide an image by using light emitted from the sub-pixels.

The peripheral area PA where an image is not provided may entirely surround the display area DA in a plan view. A driver or a main voltage supply line for providing an electrical signal or power to pixel circuits may be located in the peripheral area PA. A pad to which an electronic device or a printed circuit board may be electrically connected may be disposed in the peripheral area PA.

The display area DA may have any of polygonal shapes including a quadrangular shape as shown in FIG. 17 in a plan view. For example, the display area DA may have a rectangular shape in which a horizontal length is greater than a vertical length, or a rectangular shape in which a horizontal length is less than a vertical length, or a square shape. In another embodiment, the display area DA may have a circular shape, an elliptical shape, or a polygonal shape such as a triangular shape or a pentagonal shape. Although the display apparatus 1 of FIG. 17 is a flat panel display apparatus, the display apparatus 1 may be implemented as any of various apparatuses such as a flexible, foldable, or rollable display apparatus.

The display apparatus 1 may be used as a display screen of not only a portable electronic device such as a mobile phone, a smartphone, a tablet personal computer (PC), a mobile communication terminal, an electronic organizer, an electronic book, a portable multimedia player (PMP), a navigation device, or an ultra-mobile PC (UMPC) but also any of various products such as a television, a laptop computer, a monitor, an advertisement board, or an Internet of things (loT) product. The display apparatus 1 according to an embodiment may be used in a wearable device such as a smart watch, a watch phone, a glasses-type display, or a head-mounted display (HMD). The display apparatus 1 according to an embodiment may be used as a center information display (CID) located on an instrument panel, a center fascia, or a dashboard of a vehicle, a room mirror display replacing a side-view mirror of a vehicle, or a display screen located on the back of a front seat for entertainment for a person in a back seat of a vehicle.

The display apparatus 1 may include an organic light-emitting diode (OLED) as a display device, but the disclosure is not limited thereto. In another embodiment, the display apparatus 1 may be a light-emitting display apparatus including an inorganic light-emitting diode, for example, an inorganic light-emitting display apparatus. In another embodiment, the display apparatus 1 may be a quantum dot light-emitting display apparatus.

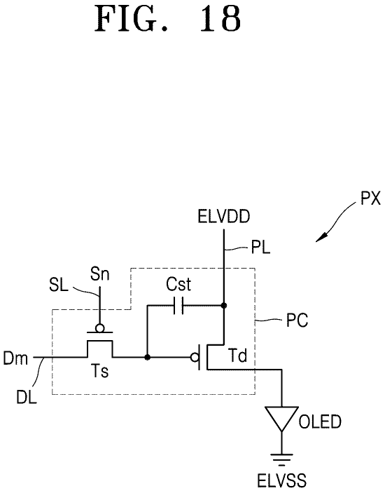

FIG. 18 is a schematic diagram of an equivalent circuit of one pixel circuit PC included in a display apparatus manufactured by using an apparatus for manufacturing a display apparatus, according to an embodiment. The pixel circuit PC may be electrically connected to a display device, and one display device may correspond to one pixel PX. For example, the display device may be an organic light-emitting diode OLED.

The pixel circuit PC may include a first transistor Td, a second transistor Ts, and a storage capacitor Cst. The second transistor Ts that is a switching thin-film transistor may be connected to a scan line SL and a data line DL, and may be turned on by a switching signal input from the scan line SL to transmit a data signal input from the data line DL to the first transistor Td. The storage capacitor Cst may have an end electrically connected to the second transistor Ts and another end electrically connected to a driving voltage line PL, and may store a voltage corresponding to a difference between a voltage received from the second transistor Ts and a driving power supply voltage ELVDD supplied from the driving voltage line PL.

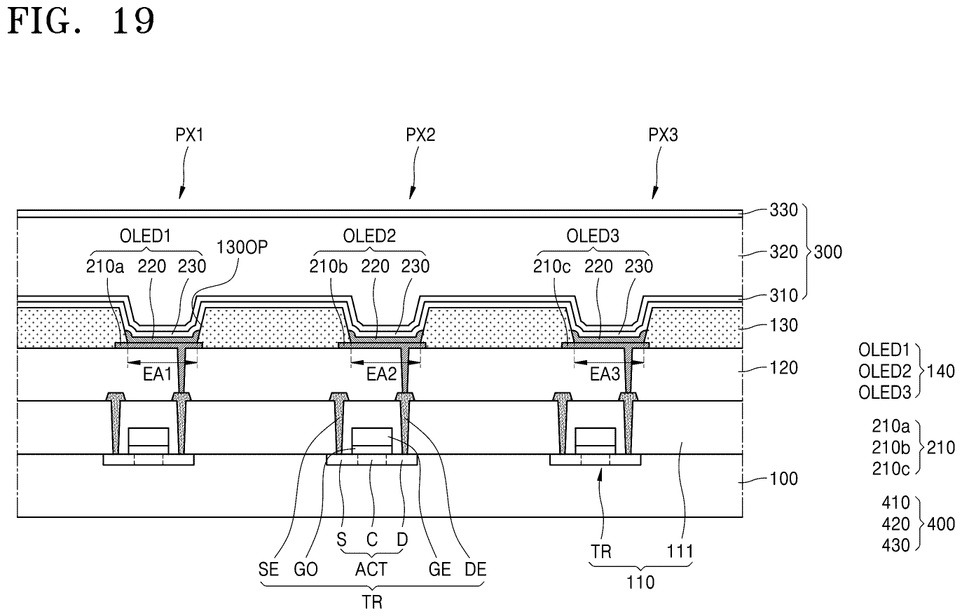

The first transistor Td that is a driving transistor may be connected to the driving voltage line PL and the storage capacitor Cst, and may control a magnitude of driving current flowing from the driving voltage line PL to the organic light-emitting diode OLED in response to a value of the voltage stored in the storage capacitor Cst. The organic light-emitting diode OLED may emit light having a luminance according to the driving current. A counter electrode 230 (see FIG. 19) of the organic light-emitting diode OLED may receive an electrode power supply voltage ELVSS.

Although FIG. 18 illustrates that the pixel circuit PC includes two transistors and one storage capacitor, the disclosure is not limited thereto. The number of transistors or the number of storage capacitors may be changed in various ways according to a design of the pixel circuit PC.

FIG. 19 is a schematic cross-sectional view schematically illustrating a display apparatus manufactured by using an apparatus for manufacturing a display apparatus, according to an embodiment.

Referring to FIG. 19, the display apparatus 1 may include a substrate 100, a pixel circuit layer 110 including a transistor TR, a via insulating layer 120 on the pixel circuit layer 110, a display device layer 140 located on the via insulating layer 120, and an encapsulation layer 300 on the display device layer 140.

The substrate 100 may have a top surface in a plane extending in the x direction and the y direction. The substrate 100 may include a semiconductor material, for example, a group IV semiconductor, a group III-V compound semiconductor, or a group II-VI compound semiconductor. For example, the substrate 100 may be a semiconductor substrate including a semiconductor material. For example, the substrate 100 may include silicon (Si). For example, the substrate 100 may be a silicon substrate (silicon semiconductor substrate). For example, the substrate 100 may be a silicon wafer. The silicon wafer may be a monocrystalline silicon wafer, a polycrystalline silicon wafer, or an amorphous silicon wafer.

As such, an organic light-emitting diode display device using a semiconductor substrate as the substrate 100 may be referred to as OLED on silicon (OLEDoS). Because OLEDoS uses a semiconductor substrate as the substrate 100, a transistor manufacturing process commonly used in the semiconductor technology field may be applied to a process of manufacturing the display apparatus. Accordingly, because the formation and control of ultra-small pixels are possible, OLEDoS may display ultra-high resolution images.

A type of the substrate 100 may not be limited to a semiconductor substrate. For example, the substrate 100 may include glass, a metal, or a polymer resin. The substrate 100 may include a polymer resin including polyethersulfone, polyacrylate, polyetherimide, polyethylene naphthalate, polyethylene terephthalate, polyphenylene sulfide, polyarylate, polyimide, polycarbonate, or cellulose acetate propionate. However, the disclosure is not limited thereto, and various modifications may be made. For example, the substrate 100 may have a multi-layer structure including two layers each including a polymer resin and a barrier layer including an inorganic material (e.g., silicon oxide (SiO_{X}), silicon nitride (SiN_{X}), or silicon oxynitride (SiO_{X}N_{Y}) and located between the two layers. The following will be described assuming that the substrate 100 is a silicon substrate.

The pixel circuit layer 110 may be located on the substrate 100. The pixel circuit layer 110 may include multiple pixel circuits respectively corresponding to pixels described with reference to FIG. 17, For example, the first sub-pixel to the third sub-pixel PX1, PX2, and PX3, and each of the pixel circuits may include a transistor and/or a storage capacitor as described with reference to FIG. 18. The pixel circuit layer 110 may include at least one transistor TR and at least one insulating layer.

Referring to FIG. 19, an organic light-emitting diode OLED may be located as a display device on the substrate 100. In case that the organic light-emitting diode OLED is electrically connected to the pixel circuit PC, it may mean that a pixel electrode 210 included in the organic light-emitting diode OLED is electrically connected to the transistor TR included in the pixel circuit PC (see FIG. 18). For convenience of illustration, because the transistors TR respectively connected to a first organic light-emitting diode OLED1, a second organic light-emitting diode OLED2, and a third organic light-emitting diode OLED3 are illustrated in FIG. 19, the transistor TR may correspond to the first transistor Td (see FIG. 18).

The transistor TR may include a gate dielectric layer GO, a gate electrode GE, and an active area ACT. The transistor TR may be, for example, but is not limited to, a metal-oxide-semiconductor field effect transistor (MOSFET). In an embodiment, the transistors TR may be separated from each other by a device isolation region located between the transistors TR.

The active area ACT may be located in the substrate 100. The active area ACT may be formed as a part of the substrate 100. The active area ACT may extend in the first direction, for example, in the x direction, in the substrate 100. A part of the substrate 100 may be recessed and the active area ACT may be located in the recessed part of the substrate 100. The active area ACT may include a channel region C, and a drain region D and a source region located on sides of the channel region C. Each of the drain region D and the source region S may be a region obtained by doping impurities into the substrate 100 including a semiconductor material. The channel region C may overlap the gate electrode GE in a plan view.

The gate dielectric layer GO may be located between the gate electrode GE and the active area ACT. The gate dielectric layer GO may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂).

The gate electrode GE may be located on the active area ACT. The gate electrode GE may intersect the active area ACT in a plan view and may extend in a direction, for example, in the y direction. The channel region C of the transistor TR may be formed on the active area ACT intersecting the gate electrode GE. For example, the gate electrode GE may overlap the channel region C of the transistor TR in a plan view. The gate electrode GE may be located on the gate dielectric layer GO. The gate electrode GE may include a conductive material. For example, the gate electrode GE may include a metal nitride such as a titanium nitride film (TiN), a tantalum nitride film (TaN), or a tungsten nitride film (WN), and/or a metal material such as aluminum (Al), tungsten (W), copper (Cu), or molybdenum (Mo), or a semiconductor material such as doped polysilicon. The gate electrode GE may have a single or multi-layer structure including the above material.

An interlayer insulating layer 111 may be located on the substrate 100 and may cover the transistor TR. The interlayer insulating layer 111 may include at least one of oxide, nitride, and oxynitride. The interlayer insulating layer 111 may have a single or multi-layer structure.

Each of a drain electrode DE and a source electrode SE may be located on the interlayer insulating layer 111. The drain electrode DE and the source electrode SE may be respectively connected to the drain region D and the source region S of the active area ACT through contact holes formed in the interlayer insulating layer 111. Each of the drain electrode DE and the source electrode SE may include a material having high conductivity. Each of the drain electrode DE and the source electrode SE may include a conductive material including molybdenum (Mo), aluminum (Al), copper (Cu), or titanium (Ti), and may have a single or multi-layer structure including the above material.

The via insulating layer 120 may be located on the pixel circuit layer 110. The via insulating layer 120 may be an organic insulating layer functioning as a planarization film by covering top surfaces of the drain electrode DE and the source electrode SE and having a substantially flat top surface. The via insulating layer 120 may include, for example, an organic material such as an acrylic material, benzocyclobutene (BCB), or hexamethyldisiloxane (HMDSO). Although the via insulating layer 120 has a single-layer structure, the disclosure is not limited thereto and the via insulating layer 120 may have a multi-layer structure.

The display device layer 140 may be located on the via insulating layer 120. For example, the display device layer 140 may include the first organic light-emitting diode OLED1, the second organic light-emitting diode OLED2, and the third organic light-emitting diode OLED3.

The first to third organic light-emitting diodes OLED1, OLED2, and OLED3 may each have a stacked structure of a pixel electrode 210, an emission layer 220, and a counter electrode 230. Each of the first to third organic light-emitting diodes OLED1, OLED2, and OLED3 may emit light having the same peak spectrum. For example, each of the first to third organic light-emitting diodes OLED1, OLED2, and OLED3 may emit white light. For example, peak spectra of the first to third organic light-emitting diodes OLED1, OLED2, and OLED3 may respectively have peaks in a first wavelength region in a range of about 435 nm to about 490 nm, a second wavelength region in a range of about 500 nm to about 590 nm, and a third wavelength region in a range of about 600 nm to about 710 nm. The first to third organic light-emitting diodes OLED1, OLED2, and OLED3 may emit light and areas where light is emitted may be respectively defined as first to third emission areas EA1, EA2, and EA3.

Multiple pixel electrodes 210 may be located on the via insulating layer 120. The pixel electrodes 210 may be electrically connected to the transistors TR through contact holes formed in the via insulating layer 120. Each of the pixel electrodes 210 may include a light-transmitting conductive layer formed of a light-transmitting conductive oxide such as ITO, In₂O₃, or IZO, and a reflective layer formed of a metal such as Al or Ag. For example, each of the pixel electrodes 210 may have a three-layer structure including ITO/Ag/ITO.

As shown in FIG. 19, the pixel electrodes 210 may include a first pixel electrode 210a, a second pixel electrode 210b, and a third pixel electrode 210c. The first to third pixel electrodes 210a, 210b, and 210c may be spaced apart from each other in a direction perpendicular to the substrate 100.

A pixel defining layer 130 may be located on the via insulating layer 120. The pixel defining layer 130 may include openings 130OP corresponding to the first to third sub-pixels PX1, PX2, and PX3. The opening 130OP of the pixel defining layer 130 may expose at least a part, for example, a central part, of each of the pixel electrodes 210. In an embodiment, the first to third emission areas EA1, EA2, and EA3 may be defined as areas exposed by the openings 130OP of the pixel defining layer 130. The pixel-defining layer 130 may include an organic insulating material and/or an inorganic insulating material. The pixel-defining layer 130 may include an organic material such as polyimide or hexamethyldisiloxane (HMDSO).

A spacer (not shown) for preventing mask damage may be further provided on the pixel-defining layer 130. In an embodiment, the spacer may be integrally formed with the pixel defining layer 130. For example, the spacer and the pixel-defining layer 130 may be simultaneously formed in a same process using a halftone mask process.

The emission layer 220 may be located on the pixel electrodes 210. The emission layer 220 may cover the pixel electrodes 210 exposed by the openings 130OP of the pixel defining layer 130. In an embodiment, the emission layer 220 may be integrally formed over the pixel electrodes 210.

The emission layer 220 may emit light of a certain color. For example, the emission layer 220 may emit white light.

In an embodiment, the emission layer 220 may include a high molecular weight organic material or a low molecular weight organic material. The emission layer 220 may include an organic emission material. For example, the emission layer 220 may include a polymer material such as a polyphenylene vinylene (PPV)-based material or a polyfluorene-based material. The emission layer 220 may be formed by using screen printing, inkjet printing, laser-induced thermal imaging (LITI), or the like. However, the disclosure is not limited thereto, and the emission layer 220 may include an inorganic light-emitting material or may include quantum dots.

In an embodiment, functional layers (not shown) may be located under and over the emission layer 220. The functional layers may include a hole injection layer (HIL), a hole transport layer (HTL), an electron transport layer (ETL), and/or an electron injection layer (EIL). The functional layers may be integrally formed over the pixel electrodes 210, or may be patterned to correspond to each of the pixel electrodes 210.

The counter electrode 230 may be located on the pixel electrodes 210 and may overlap the pixel electrodes 210 in a plan view. The counter electrode 230 may be located on the emission layer 220. The counter electrode 230 may be formed of a conductive material having a low work function. For example, the counter electrode 230 may include a (semi-) transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. In another embodiment, the counter electrode 230 may further include a layer formed of ITO, IZO, ZnO, or In₂O₃ on the (semi-) transparent layer including the above material. The counter layer 230 may be integrally formed to entirely cover the substrate 100.

The encapsulation layer 300 may be located on the counter electrode 230. The encapsulation layer 300 may cover the organic light-emitting diodes (e.g., OLED1, OELD2, and OELD3). The encapsulation layer 300 may include at least one inorganic encapsulation layer and at least one organic encapsulation layer. In an embodiment, the encapsulation layer 300 may include a first inorganic encapsulation layer 310, an organic encapsulation layer 320 on the first inorganic encapsulation layer 310, and a second inorganic encapsulation layer 330.

Each of the first inorganic encapsulation layer 310 and the second inorganic encapsulation layer 330 may include at least one inorganic material such as aluminum oxide, titanium oxide, tantalum oxide, hafnium oxide, zinc oxide, silicon oxide, silicon nitride, and silicon oxynitride. The organic encapsulation layer 320 may include a polymer-based material. Examples of the polymer-based material may include an acrylic resin, an epoxy resin, polyimide, and polyethylene. In an embodiment, the organic encapsulation layer 320 may include acrylate. The organic encapsulation layer 320 may be formed by curing a monomer or applying a polymer. The organic encapsulation layer 320 may be transparent.

Although not shown, a touch sensor layer may be located on the encapsulation layer 300, and an optical functional layer may be located on the touch sensor layer. The touch sensor layer may obtain coordinate information according to an external input, for example, a touch event. The optical functional layer may reduce a reflectance of light (external light) incident on the display apparatus and/or improve the color purity of light emitted from the display apparatus. In an embodiment, the optical functional layer may include a phase retarder and/or a polarizer. The phase retarder may be a film-type phase retarder or a liquid crystal coating-type phase retarder, and may include λ/2 phase retarder and/or a λ/4 phase retarder. The polarizer may also be a film-type polarizer or a liquid crystal coating-type polarizer. The film-type polarizer may include a stretchable synthetic resin film, and the liquid crystal coating-type polarizer may include liquid crystals arranged in an arrangement. The phase retarder and the polarizer may further include a protective film.

An adhesive member may be located between the touch sensor layer and the optical functional layer. The adhesive member may be a general member without limitation. In an embodiment, the adhesive member may be a pressure sensitive adhesive (PSA).

According to embodiments, a mask assembly may be aligned with a display substrate, and thus, the deposition quality of a deposition material may be improved.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A mask assembly comprising:
a mask frame comprising an opening area; and
a mask sheet located on the mask frame and comprising a body portion, a rib portion, and a sheet portion, wherein
the body portion is formed along a circumference of a through-area at a center and define the through-area,
the rib portion protrudes to the through-area and comprises a plurality of first ribs extending in a first direction and a plurality of second ribs extending in a second direction intersecting the first direction to define a plurality of openings, and
the sheet portion covers the through-area and comprises a plurality of pattern holes overlapping the plurality of openings in a plan view.

2. The mask assembly of claim 1, wherein
the body portion comprises a silicon material, and
the rib portion comprises a metal material.

3. The mask assembly of claim 2, wherein the sheet portion comprises a metal material or an inorganic material.

4. The mask assembly of claim 1, wherein the rib portion protrudes so that a top surface of the rib portion is at a position higher than a top surface of the body portion.

5. The mask assembly of claim 4, wherein the rib portion protrudes so that the top surface of the rib portion is higher than the top surface of the body portion by about 0.1 μm to about 5 μm.

6. The mask assembly of claim 1, wherein a portion of the sheet portion overlapping the rib portion in a plan view protrudes to be higher than a portion of the sheet portion overlapping the plurality of openings in a plan view.

7. The mask assembly of claim 6, wherein the portion of the sheet portion overlapping the rib portion in a plan view protrudes to be higher than the portion of the sheet portion overlapping the plurality of openings, by about 0.1 μm to about 5 μm.

8. The mask assembly of claim 1, wherein a thickness of the rib portion is greater than a thickness of the sheet portion and less than a thickness of the body portion.

9. The mask assembly of claim 1, wherein a thickness of the rib portion is about 1/20 to about 1/10 of a thickness of the body portion.

10. The mask assembly of claim 1, wherein a bottom surface of the rib portion is located higher than a bottom surface of the body portion.

11. The mask assembly of claim 1, wherein
the body portion comprises a receiving groove formed along an inner circumference of the body portion in a plan view, and
the rib portion is supported by and seated in the receiving groove.

12. A method of manufacturing a mask assembly, the method comprising:
forming a first groove extending in a first direction and a second groove extending in a second direction intersecting the first direction, by etching a top surface of a base layer comprising a silicon material;
forming a rib portion by forming a metal layer in the first groove and the second groove;
forming a sheet portion to cover the top surface of the base layer and the rib portion; and
removing a portion of the base layer overlapping the sheet portion in a plan view to form a through-area.

13. The method of claim 12, wherein the forming of the rib portion comprises forming the metal layer so that a top surface of the rib portion is higher than the top surface of the base layer.

14. The method of claim 13, wherein the top surface of the rib portion protrudes to be higher than the top surface of the base layer by about 0.1 μm to about 5 μm.

15. The method of claim 12, wherein a bottom surface of the rib portion is located higher than a bottom surface of the base layer.

16. The method of claim 12, wherein the forming of the sheet portion comprises forming a plurality of pattern holes by forming a second metal layer by using electroforming.

17. The method of claim 12, wherein the forming of the sheet portion comprises forming a plurality of pattern holes by forming and etching an inorganic film comprising an inorganic material.

18. The method of claim 12, wherein the forming of the sheet portion comprises allowing a portion of the sheet portion overlapping the rib portion in a plan view to protrude to be at a position higher than a portion of the sheet portion not overlapping the rib portion in a plan view.

19. The method of claim 12, wherein a thickness of the rib portion is greater than a thickness of the sheet portion and less than a thickness of the base layer.

20. The method of claim 12, wherein the removing of the portion of the base layer comprises removing the portion of the base layer so that the base layer is arranged in a ring shape along a circumference of the sheet portion.
